(19) United States
(12) Patent Application Publication
(10) Pub. No.: US 2007/0105244 A1
(43) Pub. Date: May 10, 2007

(54) Analytical apparatus, processing apparatus, measuring and/or inspecting apparatus, exposure apparatus, substrate processing system, analytical method, and program

(75) Inventor: Shinichi Okita, Tokyo (JP)

Correspondence Address: OLIFF & BERRIDGE, PLC, P.O. BOX 19928, ALEXANDRIA, VA, 22320, US

(73) Assignee: NIKON CORPORATION, TOKYO (JP)

(21) Appl. No.: 11/593,172

(22) Filed: Nov. 6, 2006

Related U.S. Application Data
(60) Provisional application No. 60/844,656, filed on Sep. 15, 2006.

(30) Foreign Application Priority Data
Nov. 4, 2005 (JP) 2005-320281

(51) Int. Cl. H01L 21/66; H01L 23/58

(52) U.S. Cl. 438/14; 257/48

(57) ABSTRACT

A line width of a pattern on a substrate that is exposed and developed in an exposure apparatus is measured by a measuring instrument. In the case the line width is judged to be abnormal (step 303), an analytical apparatus specifies an apparatus that causes a line width variation factor (step 307) based on a degree of coincidence between an actual measurement value and a simulation value of the line width, specifies a line width variation factor based on a statistical value (step 311), optimizes parameters (steps 315 and 317) or the like. With these operations, the yield in device manufacturing processes improves.

### CROSS-REFERENCE TO RELATED APPLICATIONS

This non-provisional application claims the benefit of Provisional Application No. 60/844,656 filed Sep. 15, 2006, the disclosure of which is hereby incorporated herein by reference in its entirety.

### BACKGROUND OF THE INVENTION

1. Field of the Invention

The present invention relates to analytical apparatuses, processing apparatuses, measuring and/or inspecting apparatuses, exposure apparatuses, substrate processing systems, analytical methods, and programs, and more particularly to an analytical apparatus that analyzes information related to a series of processes for forming a device pattern on an object that serves for device manufacturing, a processing apparatus that is equipped with the analytical apparatus, a measuring and/or inspecting apparatus and an exposure apparatus, a substrate processing system that is equipped with the aforementioned various apparatuses, an analytical method in which analysis is performed using the aforementioned analytical apparatus, and a program that makes a computer analyze information related to a series of processes for forming a device pattern on an object that serves for device manufacturing.

2. Description of the Background Art

Conventionally, in manufacturing steps of electron devices such as semiconductor devices or liquid crystal display devices, in order to prevent a line width of a circuit pattern or the like that is formed on a photosensitive substrate such as a semiconductor substrate (a wafer) or a liquid crystal display substrate (a glass plate) from being too much deviated from a design value, test exposure is sequentially performed while changing exposure conditions that greatly affect the line width in an exposure apparatus, for example, a focus (a positional relation between an image plane of a projection optical system and a photosensitive substrate surface with respect to an optical axis of the projection optical system) and an exposure dose, and the optimal focus and exposure dose are obtained from the exposure results. Specifically, while changing a focus in a predetermined step pitch, by changing in stages an exposure dose within a predetermined range in each step, a test pattern is sequentially transferred onto different areas on a photosensitive substrate. With this operation, on the photosensitive substrate, a plurality of transferred images of the test patterns, which are transferred under the conditions in which at least one of the focus and the exposure dose is different, are formed. Then, for example, based on a result of re-arranging the detection results of the plurality of transferred images in a matrix arrangement on a two-dimensional coordinate system that has a focus and an exposure dose as coordinate axes, the optimal focus and exposure dose are obtained.

For example, in the conventional CD (Critical Dimension) control, a pattern line width is perceived as a continuous function of a focus and an exposure dose, and the continuous function is made using an analytical software, based on measurement results of a critical line width in each exposure field by test exposure. And, from the continuous function within a two-dimensional coordinate plane that has a focus and an exposure dose as coordinate axes, the so-called process window that is a range of a focus and an exposure dose with which a permissible line width is obtained is determined, and setting values of a focus and an exposure dose within an overlapping area of the process window that is obtained with respect to a pattern of each point within a pattern area are selected as setting values on actual exposure.

In the method described above, a focus and an exposure dose that achieve a favorable pattern line width can be determined in advance. However, in the case analysis of line width variation factors and optimization of parameters related to a line width attempt to be performed during execution of processes, a period of time required for the analysis and the optimization is required to be shorter than the conventional method from a view point of throughput. Further, because variation factors of a pattern line width are actually not limited to a focus or an exposure dose, it is also required that much more variation factors can be analyzed.

### SUMMARY OF THE INVENTION

According to the first aspect of the present invention, there is provided an analytical apparatus that analyzes information related to a series of processes for forming a device pattern on an object that serves for device manufacturing, the apparatus comprising: an obtaining unit that obtains information related to processing details that are performed during execution of the series of processes by a processing apparatus that executes at least a part of the series of processes, whereby based on information obtained by the obtaining unit and information related to an actually measured size of a pattern formed on the object, a causal relation between both information is analyzed.

According to the second aspect of the present invention, there is provided a processing apparatus that executes at least a part of a series of processes for forming a device pattern on a plurality of objects that serve for device manufacturing, whereby in the middle of sequentially executing at least a part of the series of processes to the plurality of objects, information related to processing details that relates to a size of the pattern is output.

According to the third aspect of the present invention, there is provided a measuring apparatus that measures a size of a pattern formed on an object, whereby information related to measurement conditions of a size of the pattern and information related to the measurement state can be output.

According to the fourth aspect of the present invention, there is provided a measuring apparatus that measures a size of a pattern formed on an object that serves for device manufacturing, in the middle of a period in which a series of processes for forming a device pattern on the object is executed, whereby information related to measurement conditions of a size of the pattern and information related to the measurement state can be output during execution of the series of processes.

According to the fifth aspect of the present invention, there is provided a measuring apparatus that measures a size of a pattern formed on an object, whereby information related to processing details at the time when the pattern is formed on the object is requested to the outside of the apparatus.

According to the sixth aspect of the present invention, there is provided a measuring apparatus that measures a size of a pattern formed on a plurality of objects that serve for device manufacturing, in the middle of a period in which a series of processes for forming a device pattern on the objects is executed, whereby information related to processing details at the time when the pattern is formed on the objects is requested to the outside of the apparatus during execution of the series of processes.

According to the seventh aspect of the present invention, there is provided a measuring apparatus that measures a size of a pattern formed on an object, the apparatus having a receiving section that receives information related to processing details at the time when the pattern is formed on the object from the outside of the apparatus.

According to the eighth aspect of the present invention, there is provided a measuring apparatus that measures a size of a pattern formed on a plurality of objects that serve for device manufacturing, in the middle of a period in which a series of processes for forming a device pattern on the objects is executed, the apparatus having a receiving section that receives information related to processing details at the time when the pattern is formed on the objects from the outside of the apparatus during execution of the series of processes.

According to the ninth aspect of the present invention, there is provided an exposure apparatus that transfers a pattern onto a object, whereby information related to transfer conditions of the pattern onto the object and information related to a transfer state of the pattern onto the object can be output.

According to the tenth aspect of the present invention, there is provided an exposure apparatus that transfers a device pattern onto a plurality of objects that serve for device manufacturing, whereby information related to transfer conditions of the pattern onto the objects and information related to a transfer state of the pattern onto the objects can be output in the middle of sequentially executing the transfer to the plurality of objects.

According to the eleventh aspect of the present invention, there is provided a substrate processing system that executes a series of processes to form a pattern onto an object, the system comprising: a data control section that performs overall control of information related to processing details that affect a size of the pattern in each of a plurality of processing apparatuses that execute the series of processes.

According to the twelfth aspect of the present invention, there is provided a program that makes a computer analyze information related to a series of processes for forming a device pattern onto an object that serves for device manufacturing, the program making the computer execute: a procedure of analyzing a causal relation between information related to processing details that are performed during execution of the series of processes by a processing apparatus that executes at least a part of the series of processes, and information related to an actually measured size of a pattern formed on the object, based on both information.

With the apparatuses, the system and the program, in a series of processes, a causal relation between information related to a size of a pattern and information related to processing details of a processing apparatus can be automatically analyzed during execution of the series of processes, and therefore, even when line width accuracy of an exposure pattern deteriorates during an exposure processing of a plurality of wafers, prompt factor analysis and response can be made, which makes it possible to increase a fair quality ratio without decreasing production efficiency. Further, a test processing does not always have to be performed, and also parameters to be adjusted do not need to be restricted.

### BRIEF DESCRIPTION OF THE DRAWINGS

In the accompanying drawings;

FIG. 1 is a view showing a schematic configuration of a substrate processing system related to an embodiment of the present invention;

FIG. 2 is a view showing an example of tables;

FIG. 3 is a flowchart showing a flow of a processing of the substrate processing system;

FIG. 4 is a view showing a data flow of the substrate processing system; and

FIG. 5 is a flowchart showing a processing of an analytical apparatus.

### DESCRIPTION OF THE EMBODIMENTS

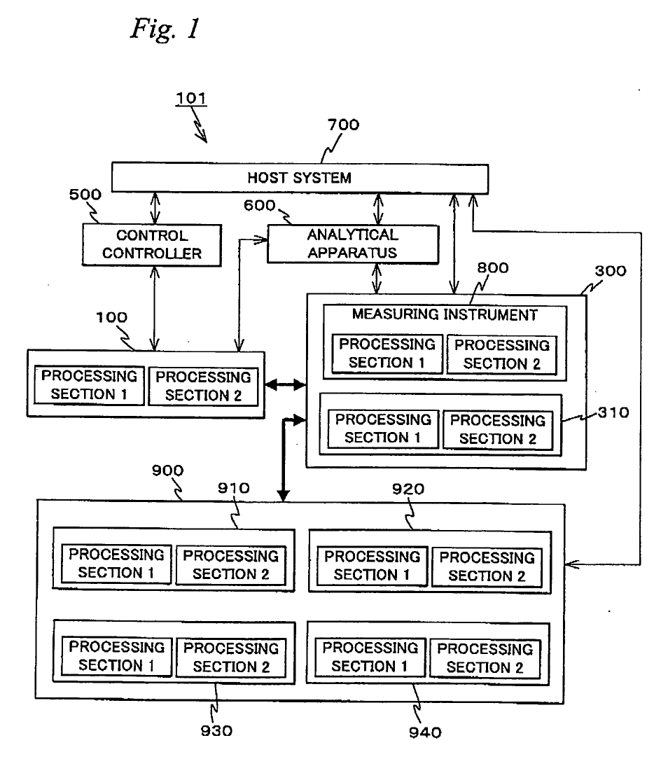

An embodiment of the present invention will be described below, with reference to FIGS. 1 to 5. FIG. 1 shows a schematic configuration of a substrate processing system related to the embodiment of the present invention. A substrate processing system 101 is a system that manufactures microdevices by processing semiconductor wafers. As is shown in FIG. 1, substrate processing system 101 is equipped with an exposure apparatus 100, a track 300 arranged adjacent to exposure apparatus 100, a control controller 500, an analytical apparatus 600, a host system 700 and a device-forming apparatus group 900.

Exposure apparatus 100 and track 300 are connected inline to each other. In this case, the inline connection means the connection between the apparatuses and between processing units within each apparatus via a transport unit such as a robot arm or a slider that transports a wafer by automation. With the inline connection, the combination of exposure apparatus 100 and track 300 can also be regarded as one substrate processing apparatus. Incidentally, due to space limitations in FIG. 1, only one substrate processing apparatus (100, 300) is shown, however, in actual, a plurality of substrate processing apparatuses are arranged in substrate processing system 101. In other words, in substrate processing system 101, exposure apparatus 100 and track 300 are arranged in plural. The respective substrate processing apparatuses (100, 300) and device-forming apparatus group 900 are arranged in a clean room where the temperature and the humidity are controlled. Further, data communication can be performed between respective apparatuses via a predetermined communication network (e.g. LAN: Local Area Network).

In the substrate processing apparatus (100, 300), wafers in plural (e.g. 25 or 50 wafers) are processed as a unit (which is called as a lot). In substrate processing system 101, wafers in one lot as a basic unit are processed and commercially manufactured.

Exposure apparatus 100 is equipped with an illumination system that emits an illumination light for exposure, a stage that holds a reticle on which a circuit pattern or the like is formed and which is illuminated by the illumination light, a projection optical system, a stage that holds a wafer subject to exposure, their control system, and the like. Exposure apparatus 100 transfers a circuit pattern of a reticle onto a plurality of different shot areas on a wafer by repeating the relative synchronous scanning of the reticle and the wafer by driving each stage described above and the stepping of the wafer, with respect to an illumination light for exposure. In other words, exposure apparatus 100 is an exposure apparatus of scanning exposure type. In exposure apparatus 100, an exposure dose control system that controls intensity (an exposure dose) of the illumination light and a stage control system that performs synchronous control of both stages, autofocus/leveling control (hereinafter, simply referred to as focus control) that makes a wafer surface conform to within a depth of focus of the projection optical system, and the like are constructed. The exposure dose control system performs feedback control so that an exposure dose coincides with a target value thereof based on the detection values of various types of exposure dose sensors capable of measuring the exposure dose. The stage control system achieves the synchronous control of both stages by performing feedback control based on the measurement values of an interferometer that measures the positions of the stages. In exposure apparatus 100, a multipoint AF (Autofocus) sensor that has a plurality of detection points at which focus/leveling deviation of a wafer surface is detected is arranged. The stage control system achieves the focus control by performing feedback control so that a wafer surface near an exposure area that is detected at, for example, 9 detection points (9 channels) out of a plurality of detection points of the multipoint AF sensor is conformed to an image plane of the projection optical system. Incidentally, in exposure apparatus 100, a two-dimensional coordinate system related to the synchronous control of both stages serves as an XY coordinate system (a synchronous scanning direction serving as a Y axis), and a coordinate axis parallel to the optical axis of the projection optical system serves as a Z axis, and the stage control is performed based on an XYZ coordinated system. In the following description, the stage control system is explained separately divided into a synchronous control system and a focus control system.

In exposure apparatus 100, control parameters used to determine operations of the respective control systems described above are settable. Such control parameters are roughly classified into adjustment system parameters and non-adjustment system parameters. The process is suspended and adjustment of an apparatus is needed in order to obtain its optimal value when a setting value of the adjustment system parameter is changed, while the adjustment of an apparatus is not needed when a setting value of the non-adjustment system parameter is changed.

As a representative example of the adjustment system parameters, regarding the exposure dose control system, there are an adjustment parameter of an exposure dose sensor that detects an exposure dose, an adjustment parameter of an illuminance measurement sensor that measures the intensity of an illumination light on a wafer surface, and the like. Further, regarding the synchronous control system, there are a parameter such as a coefficient of correction function for correcting the bending of a movable mirror that is arranged on a stage holding a wafer or a reticle and used to reflect a laser beam from an interferometer for position measurement of the stage, a position loop gain of feedback control, a velocity loop gain, an integral time constant, and the like. Further, regarding the focus control system, there are a focus offset that is an offset adjustment value of focus control when making a wafer surface on exposure conform to a projection lens image plane, a leveling adjustment parameter used to make a wafer surface on exposure conform to (be parallel to) a projection lens image plane, linearity of a position sensitive device (PSD) that is a sensor of an each detection point of the multipoint AF sensor, an offset between sensors, detection repeatability of each sensor, an offset between channels, an AF beam irradiation position on a wafer (i.e. a detection point), other parameters related to AF plane correction, and the like. Either of the values of these parameters needs to be adjusted by calibration or trial operation of an apparatus.

Meanwhile, as a representative example of the non-adjustment system parameters, regarding the exposure dose control system, for example, there are a parameter related to selection of an ND filter in an illumination system, and an exposure dose target value. Further, regarding the synchronous control system, for example, there are a scan velocity and the like. Further, regarding the focus control system, for example, there are a selection state of the focus sensor for 9 channels, a parameter related to a focus difference in level correction map to be described later, a fine adjustment amount of focus offset, a scanning direction in the case of an edge shot of a wafer outer edge, and the like. Either of the setting values of these parameters are parameters whose values can be changed without calibration of an apparatus, and most of them are designated by an exposure recipe. Incidentally, the ND filter is selected based on the result of an average power check that is performed once in a state where an exposure dose target value is appropriately set (e.g. to the minimum) when starting exposure to a wafer. Further, the scan velocity is also finely adjusted to some extent depending on the selection of the ND filter.

A line width of a circuit pattern that is transferred and formed on a wafer is deviated from a design value due to control errors of an exposure dose, synchronous accuracy and a focus. Therefore, in exposure apparatus 100, time-series data of a control amount related to an exposure dose error obtained from the exposure dose control system (exposure dose trace data), time-series date of a control amount related to a synchronous accuracy error obtained from the synchronous control system (synchronous accuracy trace data), and time-series data of a control amount related to a focus error obtained from the focus control system (focus trace data) are logged. These trace data are utilized in analysis in analytical apparatus 600, which will be described later.

Incidentally, two stages to hold a wafer are arranged in exposure apparatus 100. Wafers to be processed successively are alternately loaded onto the two stages and sequentially exposed. With this arrangement, while performing exposure to a wafer held by one stage, another wafer can be loaded onto the other stage and alignment can be performed, and therefore, throughput is improved compared with the case when wafer replacement, alignment and exposure are repeatedly performed on one stage. FIG. 1 shows a section where scanning exposure is performed to a wafer held by one stage as a processing section 1, and a section where scanning exposure is performed to a wafer held by the other stage as a processing section 2.

In track 300, a coater/developer (C/D) 310 that performs resist coating and development, and a measuring instrument 800 that performs various measurements are arranged. In C/D 310 and measuring instrument 800, processing sections 1 and 2 are also arranged to achieve the shortened processing time.

Measuring instrument 800 performs a predetermined measurement with respect to a wafer before and after (i.e. pre- and post-) exposure of the wafer in exposure apparatus 100. Measuring instrument 800 measures the so-called shot flatness (also referred to as device topography, or focus difference in level) that is an individual surface shape (unevenness) of a wafer surface, which is caused by a circuit pattern that is formed in each shot area of a previous layer on the wafer before (pre-) exposure, or the like. In measuring instrument 800, for example, an AF sensor that is matching with the AF sensor of the exposure apparatus 100 is arranged, and the shot flatness is measured by the AF sensor of the measuring instrument 800. Further, measuring instrument 800 can measure a line width of a circuit pattern or the like on the wafer after (post-) exposure that has been transferred by exposure apparatus 100 and developed by C/D 310.

Analytical apparatus 600 is an apparatus that operates independently of exposure apparatus 100 and track 300. Analytical apparatus 600 collects various types of data from various apparatuses (e.g. processing details of the apparatuses), and performs analysis of data related to a series of processes to a wafer. As a hardware to achieve such analytical apparatus 600, for example, a personal computer (hereinafter shortly referred to ‘PC’) can be employed. In this case, an analytical processing is realized by executing an analytical program that is executed by a CPU (not shown) of analytical apparatus 600. The analytical program is provided by media (information recording media) such as CD-ROM, and executed in a state being installed in the PC.

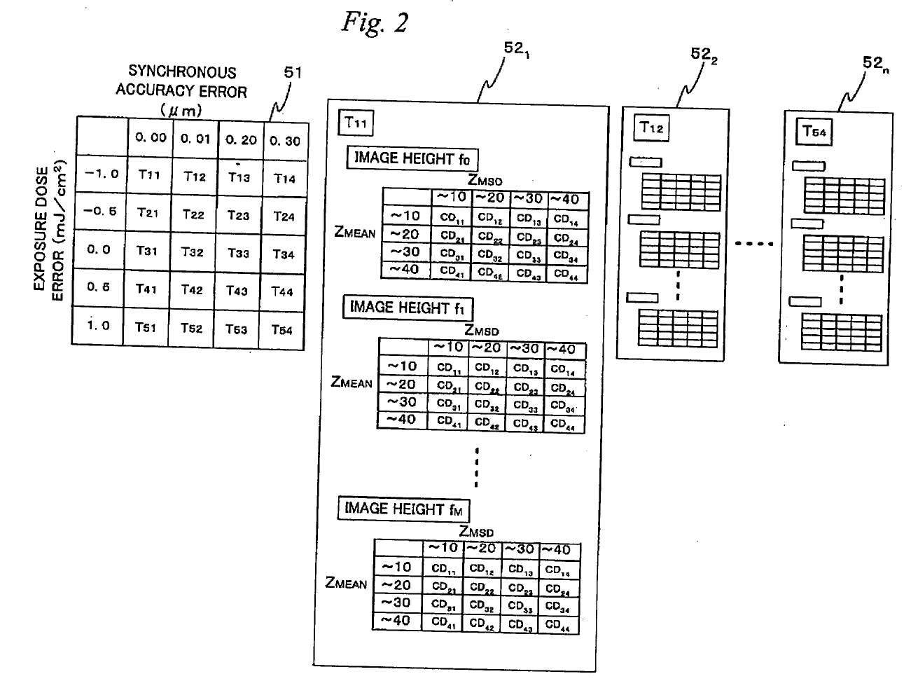

Analytical apparatus 600 can estimate a line width of a pattern that is transferred and formed on a certain point on a wafer, based on control errors of an exposure dose, synchronous accuracy and a focus when transferring the pattern on the point. In a memory (not shown) of analytical apparatus 600, table groups that show a relation between a line width of a pattern, and each control error of an exposure dose, synchronous accuracy and a focus are stored. FIG. 2 shows a model of an example of the table groups. As is shown in FIG. 2, the table groups are made up of an index table 51 and the ‘n’ number of table groups 52₁ to 52ₙ. In index table 51, as the representative value of a control error of an exposure dose (an exposure dose error), five representative values are designated out of values of −1.0 to 1.0 mJ/cm², and as the representative value of a control error of synchronous accuracy (a synchronous accuracy error), four representative values are designated out of values of 0.00 to 0.30 μm. In index table 51 in FIG. 2, as the exposure dose error, movement mean within a predetermined period is employed, and as the synchronous accuracy error, movement standard deviation within a predetermined period is employed. In either case, a statistical value that has a great influence degree on a line width is employed. In this case, the predetermined period is a period from when a slit-shaped exposure area reaches a certain point on wafer W until when the exposure area leaves the point by relative scanning of both stages.

In each cell of index table 51, either of table names (T₁₁ to T₅₄) of table groups 52ᵢ (i=1 to n, ‘n’ is, for example, 20) that corresponds to a combination of respective representative values is registered. In each table group 52ᵢ, a plurality of tables that show a relation between a Z mean offset Z_{MEAN} and a Z movement standard deviation Z_{MSD} respectively serving as a statistical value of focus control error, and a line width are prepared. In this case, Z_{MEAN} is a movement mean value of focus control error within the predetermined period described above (a passage period of the exposure slit), and Z_{MSD} is a movement standard deviation of focus control error within the predetermined period described above. More precisely, Z mean offset Z_{MEAN} and Z movement standard deviation Z_{MSD} are deviation in a Z direction and an inclination direction of a wafer surface from a focus target position when the device topography of the wafer surface is a datum, during the period when the exposure slit passes through a portion of the pattern, that is, the overall movement mean and movement standard deviation of focus control error in these directions. Incidentally, even with the same Z_{MEAN} and the same Z_{MSD}, a line width value (a CD value) at the point of time is different depending on each image height (a coordinate axis direction orthogonal to a scanning direction), and accordingly a table is prepared with respect to each of several representative values (f₀ to f_{M}) of the image height in each table group 52ᵢ.

Based on the exposure dose trace data, the synchronous accuracy trace data and the focus trace data that are obtained from exposure apparatus 100, analytical apparatus 600 computes statistical values of the respective control errors at a certain point (a sample point) on wafer W. Then, analytical apparatus 600 refers to index table 51, and based on the exposure dose error and the synchronous accuracy error, selects a table group that corresponds to the representative values close to the statistical values from among table groups 52ᵢ to 52ₙ (table names T₁₁ to T₅₄). For example, assuming that an exposure dose error is −0.7 and a synchronous accuracy error is 0.005, four tables groups 52₁, 52₂, 52₅ and 52₆ (table names T₁₁, T₁₂, T₂₁ and T₂₂) that are registered in the cells corresponding to the combinations of the representative values close to these values are selected.

The computation method of a CD value in the case four table groups are selected will be described. As a premise, out of the representative values of the exposure dose error corresponding to the selected table groups, the smaller one is called as the exposure dose error minimum value, and the greater one is called as the exposure dose error maximum value. Further, out of the representative values of the synchronous accuracy error corresponding to the selected table groups, the smaller one is called as the synchronous accuracy error best value, and the greater one is called as the synchronous accuracy error worst value. Analytical apparatus 600 refers to a table of an image height fₖ (k=0 to M) corresponding to an X coordinate of an alignment mark within a shot from among the selected four table groups, and reads out the following four tables. In this case, k=0 means that an image height is zero, that is, the image height is on the optical axis.
(1) table 1 of image height fₖ of a table group with the exposure dose error minimum value and the synchronous accuracy error best value
(2) table 2 of image height fₖ of a table group with the exposure dose error minimum value and the synchronous accuracy error worst value
(3) table 3 of image height fₖ of a table group with the exposure dose error maximum value and the synchronous accuracy error best value
(4) table 4 of image height fₖ of a table group with the exposure dose error maximum value and the synchronous accuracy error worst value

First, analytical apparatus 600 refers to tables 1 and 2 and reads out the CD values corresponding to Zₘₑₐₙ and Z_{MSD}. Then, by the first order interpolation based on the internal division ratio of the synchronous accuracy error when internally dividing values between the synchronous accuracy error worst value and the synchronous accuracy error best value, analytical apparatus 600 computes a CD value corresponding to the synchronous accuracy value from the CD values read out from tables 1 and 2. More specifically, two CD values, which are read out from two tables 1 and 2 within a two-dimensional plane that has CD and a synchronous accuracy error as coordinate axes, and an intercept and an inclination of a straight line that has points corresponding to the two CD values at both end (i.e. an expression of the straight line) are obtained, and a CD value of the point on the straight line corresponding to synchronous accuracy error is obtained as a CD value corresponding to the synchronous accuracy error. Likewise, analytical apparatus 600 refers to tables 3 and 4, and reads out the CD values corresponding to Z_{MEAN} and Z_{MSD}. Then, by the first order interpolation based on the internal division ratio of the synchronous accuracy error when internally dividing values between the synchronous accuracy error worst value and the synchronous accuracy error best value, analytical apparatus 600 computes a CD value corresponding to the synchronous accuracy error from the CD values read out from tables 3 and 4. Subsequently, from the two computed CD values, by the first order interpolation based on the internal division ratio of the exposure dose error value that internally divides values between the exposure dose error minimum value and the exposure dose error maximum value, analytical apparatus 600 computes a CD value corresponding to the control error of the exposure dose. This CD value is a CD value at the sample point. As a matter of course, the interpolation described above is also applied to the case when one of values of exposure dose error and synchronous accuracy error is equal to the representative value, and not four but two tables are selected.

In the meantime, prior to estimation of a line width using the tables, CD values need to be registered in the tables in advance. The CD values are registered before executing a series of processes, based on information obtained from exposure apparatus 100 and measuring instrument 800. First, exposure apparatus 100 is made to transfer a test pattern onto a test wafer by performing scanning exposure in a state where predetermined exposure conditions are set, and to obtain exposure dose trace data, synchronous accuracy trace data and focus trace data at the time of the scanning exposure. Then, C/D 310 is made to develop the test wafer on which the test pattern has been transferred, and measuring instrument 800 is made to measure a line width of the test pattern. And, various types of trace data and data related to the set exposure conditions, and measurement results of a line width are forwarded to analytical apparatus 600.

Analytical apparatus 600 computes statistical values of control errors of an exposure dose, synchronous accuracy and a focus at a sample point to which the test pattern whose line width is measured is transferred, based on the various types of trace data. Next, analytical apparatus 600 divides the measurement results into groups, with respect each predetermined range (i.e. each cell within a table) that has the representative value of each type of control errors set in the table as a datum. Then, the mean value of the measurement results of a line width that belong to the same group is registered as a CD value of the cell. Incidentally, the CD value to be registered does not need to be based on the measurement results of measuring instrument 800, and may also be based on a value measured by SEM or a value measured by an OCD method or the like. Or, an aerial image sensor that measures an aerial image of a test pattern is arranged instead, without using a test wafer actually, and the CD value to be registered may be a computed value by aerial image simulation that is obtained from the aerial image of the test pattern measured by the aerial image sensor.

Incidentally, even with the same exposure dose error, the same synchronous accuracy error and the same focus error, CD values are different depending on exposure conditions of exposure apparatus 100 and design conditions of a pattern to be transferred. Therefore, the table group is prepared with respect to each exposure condition and each pattern design condition. In this manner, it is necessary to make a database beforehand of the table groups so that an estimated value of a CD value can be searched for using an exposure condition, a pattern design condition, an exposure dose error, a synchronous accuracy error and a focus error as a key. Incidentally, as the exposure conditions, there are an exposure wavelength, a projection optical system NA, an illumination NA, an illumination σ, an illumination type, a depth of focus and the like, and as the pattern design conditions, there are a design line width (e.g. 130 nm), a pattern type (an isolated line, or a line-and-space pattern) and the like. The details of a relation between the exposure conditions and the pattern design conditions, and a pattern line width, and of the setting method of other conditions such as an image height in the tables are disclosed in, for example, in Kokai (Japanese Unexamined Patent Application Publication) No. 2001-338870.

Control controller 500 controls and manages an exposure step that is performed in exposure apparatus 100, and controls a scheduling of exposure apparatus 100. Further, host system 700 performs overall control over substrate processing system 101. Device-forming apparatus group 900 includes a film-forming apparatus (CVD (Chemical Vapor Deposition) apparatus) 910 that forms a thin film on a wafer, an etching apparatus 920 that performs etching, a CMP (Chemical Mechanical Polishing) apparatus 930 that performs a processing of planarizing a wafer by chemical mechanical polishing, an oxidization/ion-implantation apparatus 940 that oxidizes a wafer and implants ion (impurities), and the like. In CVD apparatus 910, etching apparatus 920, CMP apparatus 930 and oxidization/ion-implantation apparatus 940, two processing sections (processing sections 1 and 2) are also arranged, and improvement in throughput is aimed. Further, CVD apparatus 910, etching apparatus 920, CMP apparatus 930 and oxidization/ion-implantation apparatus 940 are also arranged in plural similarly to exposure apparatus 100 and the like, and a transport route used to transport a wafer between them is arranged. Besides, in device-forming apparatus group 900, an apparatus that performs a probing processing, a repair processing, a dicing processing, a packaging processing and a bonding processing of a wafer is also included.

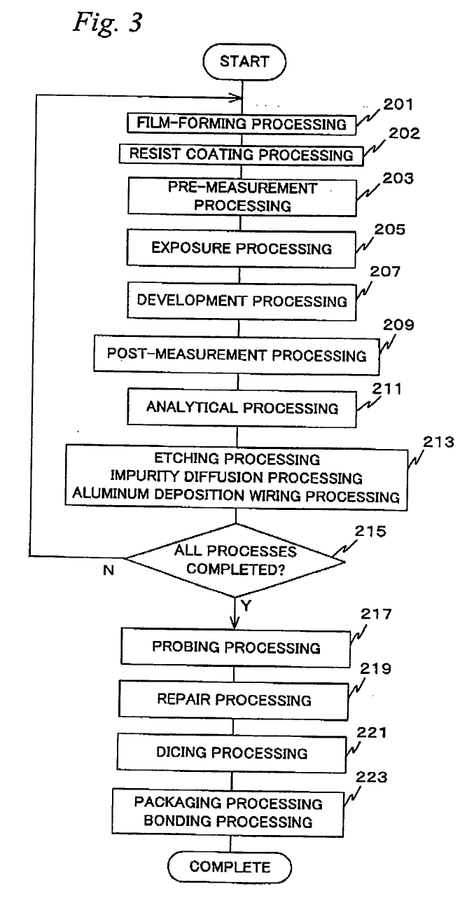

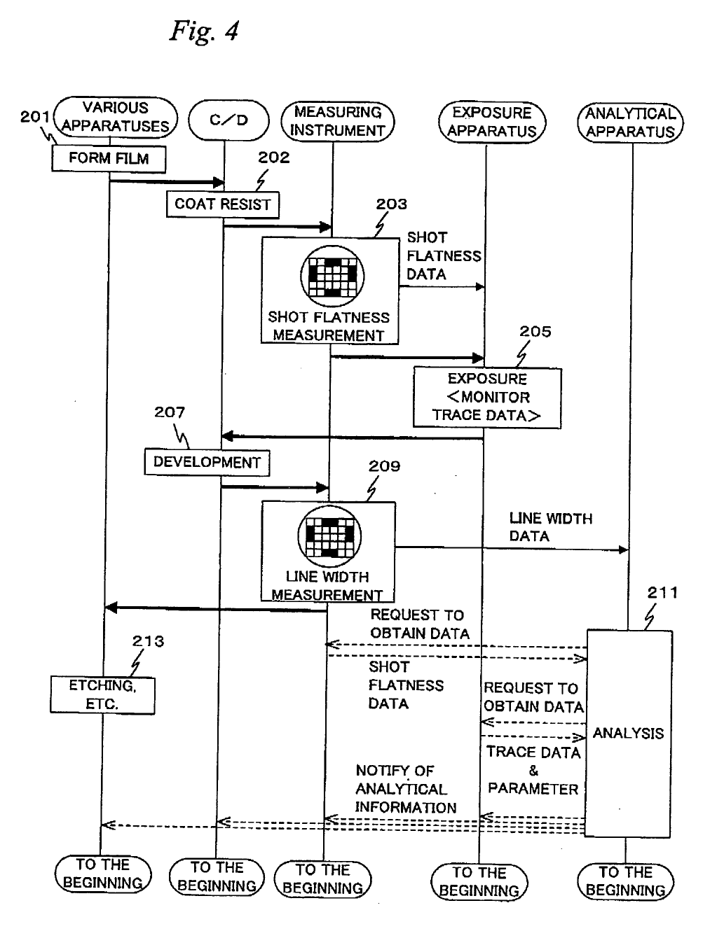

Next, a flow of a series of processes in substrate processing system 101 will be described. FIG. 3 shows a flowchart of the processes, and FIG. 4 shows a wafer flow and a data flow in a part related to repeated steps in the series of processes. The series of processes in substrate processing system 101 is scheduled and controlled by host system 700 and control controller 500. As is described above, wafers are processed per each lot, however, FIGS. 3 and 4 both show the series of processes to one wafer. In actual, the processing shown in FIGS. 3 and 4 is repeated to wafers per each lot.

As is sown in FIGS. 3 and 4, first, a film is formed on a wafer in CVD apparatus 910 (step 201), the wafer is transported to C/D 310, in which resist is coated on the wafer (step 202). Next, the wafer is transported to measuring instrument 800, in which with regard to a shot area selected as a measurement subject (hereinafter referred to as a measurement shot) from among a plurality of shot areas of the previous layer already formed on the wafer, shot flatness (a focus difference in level of a shot area) is measured (step 203). The number and the arrangement of the measurement shot can be any number and any arrangement, for example, as is shown in FIG. 4, eight shots arranged in an outer edge of the wafer may be selected. Measurement results of measuring instrument 800 (i.e. the shot flatness of the measurement shots) are sent to exposure apparatus 100. The measurement results are used for focus control when performing scanning exposure in exposure apparatus 100.

Then, the wafer is transported to exposure apparatus 100, in which a circuit pattern on a reticle is transferred onto the wafer (step 205). At this point of time, exposure apparatus 100 monitors the exposure dose trace data, the synchronous accuracy trace data and the focus trace data during exposure of the measurement shots, and stores them in an internal memory. Next, the wafer is transported to C/D 310, in which development is performed (step 207). A line width of a resist image is measured by measuring instrument 800 (step 209). Measurement results of measuring instrument 800 (line width data) is sent to analytical apparatus 600. Analytical apparatus 600 performs analysis related to the line width based on information from exposure apparatus 100 and/or measuring instrument 800 (step 211). As is shown in FIG. 4, analytical apparatus 600 sends out a forwarding request of various types of data to measuring instrument 800 and/or exposure apparatus 100 as needed as a result of the analysis, and/or sends out analytical information to the respective apparatuses in accordance with the analytical results. Incidentally, the details of an analytical processing and a data flow in analytical apparatus 600 will be described later. Further, after analytical apparatus 600 obtains various types of data, exposure apparatus 100 may immediately delete the trace data and the like stored inside.

Meanwhile, the wafer is transported from measuring instrument 800 to etching apparatus 920 included in device-forming apparatus group 900, and in etching apparatus 920, etching is performed, and then impurity diffusion, a aluminum evaporation wiring processing, film-forming in CVD apparatus 910, planarization in CMP apparatus 930, and ion implantation in oxidization/ion-implantation apparatus 940 are performed, as needed (step 213). Then, host system 700 judges whether or not all steps are completed and all patterns are formed on the wafer (step 215). When the judgment is denied, the procedure returns to step 201, and when the judgment is affirmed, the procedure proceeds to step 217. In this manner, by repeatedly executing a series of processes from the film-forming/resist coating to the etching and the like in accordance with the number of steps, circuit patterns are transferred and overlaid on the wafer and a semiconductor device is formed.

After the repeated steps are completed, a probing processing (step 217) and a repair processing (step 219) are executed in device-forming apparatus group 900. In step 219, when a memory defect is detected, for example, a processing of replacing to a redundant circuit is performed. Analytical apparatus 600 may also forward information on the detected position where abnormality in line width is generated and the like to the apparatus that performs the probing processing and the repair processing. In an inspecting apparatus (not shown), the position on the wafer where the abnormality in line width is occurring can be excluded from a processing subject of the probing processing and the repair processing. After that, the dicing processing (step 221), and the packaging processing and the bonding processing (step 223) are executed, and a product chip is finally completed. Incidentally, a post-measurement processing in step 209 may also be performed after the etching in step 213. In this case, a line width measurement is performed to an etching image of the wafer.

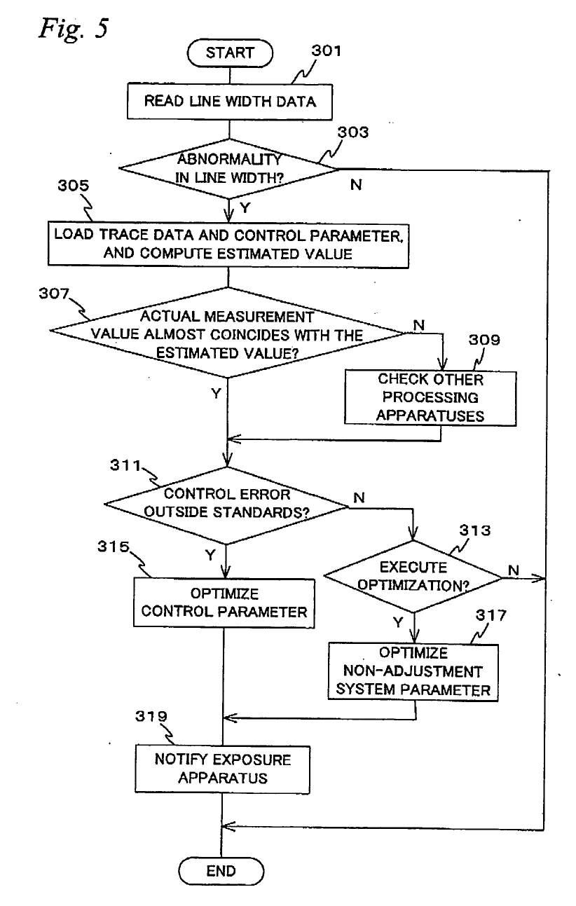

Next, the analytical processing in step 211 will be described in detail. FIG. 5 shows a flowchart of the analytical processing in analytical apparatus 600. As is shown in FIG. 5, first, line width information at each sample point of the measurement shots that has already been sent from measuring instrument 800 is read (step 301), and the judgment is made of whether a line width is abnormal or not (step 303). This judgment is performed, for example, by comparing a difference between the actually measured line width and a design value with a threshold value determined in advance. Then, in the case the line width is judged to be normal, the analytical processing finishes, and in the case the line width is judged to be abnormal, the procedure proceeds to step 305. In step 305, the focus trace data, the synchronous accuracy trace data, the exposure dose trace data, the flatness data of the wafer, and design values of the control parameters are loaded from exposure apparatus 100, and, Z_{MEAN} and Z_{MSD} that are the statistical values of focus control errors, a synchronous accuracy error (a movement standard deviation) and an exposure dose error (a movement mean) are computed based on these data, and an estimated value of a line width corresponding to the synchronous accuracy error and the exposure dose error, Z_{MEAN} and Z_{MSD} is computed referring to the table groups described earlier. Next, the judgment is made of whether the tendency of the estimated value of the line width coincides with the tendency of the actual measurement value to check consistency between them (step 307). When the tendencies do not coincide with each other, it can be regarded that there are factors of the line width abnormality in a processing other than the exposure processing (such as the film-forming/resist-coating processing, the pre-measurement processing, the development processing and the post-measurement processing). In this case, the procedure proceeds to step 309, and by sending a suspension request of the process, as the analytical information (refer to FIG. 4), to C/D 310, the respective apparatuses in device-forming apparatus group 900 and the like, the operations of various apparatuses are suspended once so as to be in a state where an operator can check other apparatuses. The operator inspects the apparatuses other than exposure apparatus 100, and searches the factors of the line width abnormality. Meanwhile, when the actual measurement value and the estimated value substantially coincide with and the judgment is affirmed in step 307, it is judged that the line width abnormality is caused by exposure apparatus 100 and the procedure proceeds to step 311.

In step 311, the judgment is made of whether or not each control error of the focus, the synchronous accuracy and the exposure dose computed in step 305 described above and a device difference in level are outside standards. For example, in the case the statistical value related to the focus is outside standards, it is judged that the focus control or the shot flatness is included as the factor of line width abnormality. Further, in the case the statistical value related to the synchronous error is outside standards, it is judged that the synchronous error is included as the factor of line width abnormality. Further, in the case the statistical value related to the exposure dose is outside standards, it is judged that the exposure dose error is included as the factor of line width abnormality. In the case at least one of these statistical values is outside standards (specifications of the exposure apparatus), the judgment is affirmed and the procedure proceeds to step 315. In step 315, an adjustment system parameter and a control system parameter that are related to a control error specified as the factor of line width abnormality are selected, and the selected parameters are optimized.

When the selected parameters are optimized, the control parameters may be adjusted so that each control error is approximated to zero, by referring to the tables shown in FIG. 2 and executing simulation using the varied combinations of the control error of the focus, the exposure dose and the synchronous accuracy. Since the relation between each control parameter and each control error of the focus, the exposure dose and the synchronous accuracy is already known, a setting value of the control parameter used to approximate each control error to zero can be determined.

Meanwhile, in the case all the statistical values of the control errors are within standards in step 311, the judgment is denied and the procedure proceeds to step 313. In step 313, the judgment is made of whether or not the optimization of control parameters should be performed even when the statistical value of each control error is within standards. When the judgment is denied, the analytical processing finishes, and when the judgment is affirmed, the procedure proceeds to step 317. In step 317, only the non-adjustment system parameter out of the control parameters is optimized (adjusted). In this case, as in step 315 described above, the control parameter (only the non-adjustment system parameter) is adjusted so as to approximate each control error to zero. In this manner, a line width of a pattern can be adjusted without suspending the exposure processing in exposure apparatus 100.

After executing steps 315 and 317, data of the optimized control parameter is forwarded to exposure apparatus 100, as the analytical information (refer to FIG. 4) (step 319). In exposure apparatus 100, the setting value of the control parameter is updated to a value of the forwarded data, and afterwards, the exposure processing continues with the updated control parameter. After executing step 319, the analytical processing finishes.

As is described in detail above, with analytical apparatus 600 related to the embodiment, in a series of processes to manufacture a device on a wafer, a causal relation between data related to a line width of a pattern that is formed on the wafer, and data related to processing details of an exposure apparatus, that is, processing conditions such as exposure conditions and pattern design information, each control error of an exposure dose, synchronous accuracy and a focus, and the like can be automatically analyzed during execution of the series of processes. With this operation, not only a test processing becomes unnecessary, but also parameters to be adjusted do not need to be limited to those related to an exposure dose and a focus.

Further, in the embodiment, since analytical apparatus 600 performs analysis only in the case line width abnormality is identified, a needless analytical processing is not performed. In the embodiment, when a difference between a line width actual measurement value and a design value exceeds a threshold value even at only one point out of sample points in a measurement shot, line width abnormality is considered to occur. In this manner, line width abnormality can be strictly detected in a measurement shot.

However, in the line width abnormality detection, line width abnormality may be detected by computing a statistical value related to an actual measurement value of a line width in a measurement shot and comparing the computed statistical value with a threshold value. In this case, influence of a measurement error included in the actual measurement value is reduced, which makes it possible to detect line width abnormality more exactly. As such a statistical value, a mean value of line width may be employed, or an index value that indicates variation of line width (such as standard deviation, so-called 3σ that is a triple of standard deviation, and variance) may be employed. Further, the sum of the mean value and the index value indicating the variation (such as the mean value of line width+3σ) may be employed.

Further, in the embodiment, in the case line width abnormality is detected, the control parameter of exposure apparatus 100 is optimized, however, any measures needs to be taken also with respect to a wafer where line width abnormality is detected. For example, with respect a wafer where line width abnormality is identified in most of measurement shots, because there is a high possibility that line width abnormality occurs in shot areas other than the measurement shots, the wafer itself can be rejected and excluded from the subsequent processing subject. Further, with respect to a wafer where the number of measurement shots in which line width abnormality is identified is, for example, one or so, because line width abnormality is considered to occur locally, a portion around a pattern that has the line width abnormality, for example, only that measurement shot can also be designated as a shot area to be excluded from the subsequent processing subject. Further, in the case a plurality of chip areas are included within one shot area, the chip area including a circuit pattern that has line width abnormality can be excluded per chip from the subsequent processing subject. As the subsequent processing, for example, there are the probing processing, the repair processing and the like. In this manner, processing efficiency can be improved by omitting these processing with respect to the portion where problems occur. Incidentally, in the case many line width abnormalities continuously occur in a plurality of wafers while processing wafers per lot, all the wafers in the lot may be rejected. By excluding a chip area, a shot area, a wafer, a lot or the like that includes a circuit pattern in which line width abnormality is detected from the subsequent processing in this manner, the efficiency of the processing can be improved. Incidentally, information related to such reject is also sent to the respective apparatuses as the analytical information shown in FIG. 4. Based on the information, the respective apparatuses do not perform the processing to the chip area, the shot area, the wafer, the lot or the like that is subject to reject.

Further, in the embodiment, one judgment level (threshold value) of line width abnormality is employed, however, the judgment level can also be set in plural stages. With the judgment level in plural stages, it becomes possible to change a processing state of various apparatuses to be executed afterward, in accordance with each judgment level. For example, two threshold values, i.e. a low threshold value and a high threshold value are set, and in the case the difference between an actually measured line width and a design value is intermediate between the two threshold values, only the control parameter of exposure apparatus 100 is optimized and a pattern reject is not performed. And in the case the difference between the actually measured line width and the design value exceeds the high threshold value, both the optimization of the control parameter and a pattern reject can be performed. Further, not limited to the above example, it becomes possible to adjust step-by-step the processing details of not only exposure apparatus 100 but also of C/D 310, measuring instrument 800, the respective apparatus in device-forming apparatus group 900, and the like.

Further, in the embodiment, measuring instrument 800 measures a line width of only the measurement shot that has been selected in advance on each wafer, however, the frequency of line width measurement may be increased or decreased in accordance with occurrence frequency of abnormality, or a distribution of line width measurement positions may be changed in accordance with abnormality occurrence distribution (the positions where abnormality occurs may be mainly measured). For example, in the case the number of measurement shots where line width abnormality is identified increases, the number of measurement shots in the wafer can be increased, and in the case the number of measurement shots where line width abnormality is identified decreases, the number of measurement shots in the wafer can be reduced. Further, the measurement of line width abnormality does not need to be performed to all wafers, and may be performed to every several wafers. For example, when abnormality in line width does not occur in a predetermined number of wafers in a row, the line width measurement may be performed to every three wafers, and then, when abnormality in line width does not occur consecutively, the frequency of the line width measurement may be every ten wafers, and eventually the line width measurement may be performed to only a wafer at the head of a lot. However, in the case abnormality in line width newly occurs, it is a matter of course that the measurement frequency of a line width needs to be increased.

Incidentally, in the case abnormality in line width is identified, analytical apparatus 600 may notify various processing apparatuses that the abnormality is identified, as the analytical information.

Incidentally, in the embodiment, the optimization of the control parameter is performed only in the case abnormality of a pattern is detected. However, the present invention is not limited to this, the optimization of the control parameter may be always performed to every several wafers. In this case, in step 303 (FIG. 5), the judgment is made of whether or not a wafer is subject to the optimization. Further, also in this case, as described above, the number of wafers subject to the optimization can be increased or decreased according to the detection frequency of a pattern that is judged to have abnormality in line width.

Incidentally, in the embodiment, the causal relation between the processing details of exposure apparatus 100 and a pattern line width on a wafer is mainly analyzed. However, a processing apparatus that affects the pattern line width is not limited to the exposure apparatus. For example, coating unevenness of resist that is coated on the wafer in C/D 310, and the like significantly affect a line width of a formed pattern. Accordingly, it is more preferable that a causal relation between other processing apparatuses than the exposure apparatus and a pattern line width can be analyzed, and whether a variation factor of the line width is attributable to the exposure apparatus or other processing apparatuses can be specified. Thus, in the embodiment, based on a degree of coincidence between an estimated value of a line width of a circuit pattern that is estimated from a processing state of the exposure apparatus and an actual measurement value of the line width, the judgment is made of whether or not the variation factor of the size of the circuit pattern on the wafer is attributable to the exposure apparatus, and when the judgment is made that the factor is not attributable to the exposure apparatus, other processing apparatuses are checked. The estimated value is estimated based on the table groups (refer to FIG. 2) that shows a relation between the processing details of exposure apparatus 100 that has been obtained previously and a line width of a circuit pattern. With this operation, reliability of the estimated value of a line width increases.

In the embodiment, the processing details of the exposure apparatus include a processing state (each control error of the focus, the exposure dose and the synchronous accuracy during scanning exposure) besides the processing conditions such as the exposure conditions and design information of a pattern. A table that shows a relation between the processing state of the exposure apparatus and a line width of a circuit pattern is prepared with respect to each of a plurality of different setting values of the processing. In the table, only a sample value of the relation between the processing details of the exposure apparatus and a line width of a circuit pattern is registered. However, even when what value the processing details of the exposure apparatus has, an estimated value of the line width corresponding to the processing details can be computed by interpolating computation. In this manner, a capacity of the memory in which the tables are stored can be reduced, and also the time required for obtaining the estimated value of the pattern line width can be shortened compared with the case tables that have enormous numbers of cells are searched. That is, the table control becomes simpler.

Incidentally, the table groups may be prepared not only with respect to each exposure condition in the exposure apparatus but also with respect to each processing result of other processing apparatuses in addition to the exposure condition. For example, the film thickness of resist that is coated by C/D 130 can be added as a processing condition similar to the exposure conditions and the like. A processing apparatus that corresponds to such a processing condition is mainly a pre-processing apparatus that performs a processing before exposure. As the pre-processing apparatus, for example, there are C/D 310 that performs coating on the wafer with resist and measuring instrument 800 that measures shot flatness. As the processing details of measuring instrument 800, there are an error value included in the processing result and the like. Further, even processing conditions of a post-processing apparatus that performs a processing after exposure can be added to the processing conditions in the tables. For example, a measurement error in measuring instrument 800, a PEB processing condition (such as temperature uniformity) and a development processing condition in C/D 310 can be added as the processing conditions. Also, in the case a measurement subject in measuring instrument 800 is not a resist image but an etching image, the processing result of the etching apparatus can be added as the processing condition. In this manner, the line width abnormality can be detected, the apparatus to which the line width variation factor is attributable can be specified, and the line width variation factor can be specified, taking into consideration the processing details of not only the exposure apparatus but also of various processing apparatuses.

Further, in the embodiment, based on each trace data of the focus, the exposure dose and the synchronous accuracy of the exposure apparatus, a variation factor of a line width of a circuit pattern is specified from among the trace data. In the specifying method, a statistical value of a control error that is computed from the respective trace data and becomes a potential variation factor during transfer of the pattern is compared to a stipulated value of the control error, and the statistical value that is outside standards is specified as a variation factor of the line width. As such a statistical value, a movement mean value and movement standard deviation of the control error can be employed. With respect to the synchronous accuracy, since the movement standard deviation, which shows the variation, shows the influence to a line width more directly than the movement mean value, the movement standard deviation is employed in the embodiment. However, the movement mean may be employed with respect to the synchronous accuracy as a matter or course, and both the movement mean and the movement standard deviation may be employed with respect to the synchronous accuracy and the exposure dose in the same manner as with the focus. Further, the statistical values of the control error of the focus are the Z mean offset (movement mean) and the Z movement standard deviation, however, besides them, an SFQR and an SFQD may also be employed.

Further, in the embodiment, measuring instrument 800 measures shot flatness of a wafer before exposure, however, the present invention is not limited to this. For example, after a wafer is loaded in the exposure apparatus, shot flatness may be measured based on variation of a wafer surface that is observed by a focus control system when the wafer is synchronously scanned similar to scanning exposure while keeping a stage that holds the wafer in a horizontal position (that is, without performing the focus control). Alternatively, a gradient that is obtained by subtracting the Z position and an inclination amount of a wafer stage from focus trace during the previous scanning exposure may be measured as shot flatness data. Incidentally, the details of such a measurement method of shot flatness data is disclosed in, for example, Kokai (Japanese Unexamined Patent Application Publication) No. 2001-338870.

Incidentally, in the embodiment, the Z mean offset and Z movement standard deviation that are the statistical values of the control error of the focus are based on flatness (device topography) as a datum. However, the present invention is not limited to this, and when computing the control error of the focus, shot flatness does not need to be considered.

Further, in the embodiment, as adjustment information used to adjust the processing details specified as the variation factor of a size of the pattern, the optimal value of the control parameter is computed. In this case, in principle, various control parameters are adjusted so as to approximate the statistical values of the focus, the exposure dose, and the synchronous accuracy to zero, referring to the tables that show a relation between the statistical values of the processing details in the exposure apparatus and a line width of a pattern. However, in the case such adjustment is difficult, the control parameters may be adjusted so as to cancel out the influence of the processing details that are specified as the variation factor to a line width of the pattern. Also in this case, the table groups described above can be utilized for adjustment of the control parameters. In other words, a cell in which various statistical values are not zero but a line width is the same as the design value is searched for and the control parameter can be adjusted so that the statistical values become the design values. Further, since the processing details that affect the line width in particular can be specified by referring to the table including the cell, the range of the control parameters to be adjusted can be narrowed to the control parameters related to the specified processing details. With this operation, the number of the control parameters to be adjusted can be reduced, which also makes it possible to improve the adjustment efficiency. Further, in the case such as when the adjustment of the control parameters is difficult by only adjusting the focus, the synchronous accuracy and the exposure dose, the exposure conditions and the design conditions of the pattern can also be changed. In this case, the processing conditions of other processing apparatuses such as the film thickness of resist coated by C/D 310 and the PEB temperature control may be changed.

Further, in the embodiment, in the case the control parameters attempt to be optimized even when the exposure dose, the synchronous accuracy and the focus are not outside standards, not the adjustment system parameters but only the non-adjustment system parameters are subject to adjustment. In this manner, because the operation of the apparatus does not need to be suspended, throughput is improved.

As is described so far, substrate processing system 101 related to the embodiment is equipped with analytical apparatus 600, and analyzes the processing details of various processing apparatuses that execute at least a part of a series of processes to a wafer using analytical apparatus 600, specifically, detects abnormality in line width of a pattern formed on the wafer, specifies the apparatus that causes a factor of line width abnormality and specifies the processing details that cause a factor of the line width abnormality. Therefore, throughput can be improved by omitting complicated steps in which a plurality of different processing conditions are severally and sequentially set in the exposure apparatus and test exposure is performed every time when the different processing conditions are set. Besides the number of variation factors of a line width that can be adjusted is not restricted and the larger number of parameters can be adjusted, which makes it possible to perform detailed adjustment of the apparatuses and to improve accuracy in the pattern line width. As a consequence, prompt response to abnormality in line width and the like, and immediate optimization of parameters become possible, and the yield of device manufacturing is improved.

In substrate processing system 101 related to the embodiment, in the analytical processing in analytical apparatus 600, respective processing apparatuses such as exposure apparatus 100 and measuring instrument 800 can send their processing details respectively to analytical apparatus 600. For example, exposure apparatus 100 can output not only information related to the processing results but also information related to the processing conditions, a state in the middle of the processing and the like to the outside of the apparatus. Incidentally, measuring instrument 800, C/D 310, and each apparatus in device-forming-apparatus group 900 may similarly output not only their processing results but also information related to the processing conditions and the processing states to analytical apparatus 600. For example, measuring instrument 800 may be capable of outputting data related to measurement conditions of a line width of the pattern (such as an illumination condition and an illumination wavelength) and data related to measurement states (such as data related to bias and variations of measurement errors). In this case, similar to exposure apparatus 100 and measuring instrument 800 related to the embodiment, when the processing conditions and the processing states can be output also in the middle of the period in which a series of processes is executed, it becomes possible to rapidly perform analysis using the data and to promptly cope with line width abnormality and the like.

Further, in the embodiment, the analytical results of analytical apparatus 600 are sent as the analytical information to exposure apparatus 100 and also to C/D 310, measuring instrument 800, and device-forming apparatus group 900. Each apparatus has a receiving section that receives the analytical information. The analytical information includes adjustment information on control parameters of each apparatus, and each apparatus changes setting values of its own control parameters based on the adjustment information. In this manner, apparatus adjustment can be performed also during execution of a series of processes, which makes it possible to promptly cope with deterioration in line width.

For example, with regard to the control parameters of measuring instrument 800, there are, for example, selection of wafers to be measured, and selection of measurement shots. For example, in FIG. 4, eight shot areas located in the outer edge of a wafer are selected as measurement shots, however, in the case these shot areas are judged not to be appropriate as measurement shots due to coating unevenness of resist or the like, the measurement shots can be changed. In a sense, adjustment of the frequency of line width measurement described above can be said to be parameter adjustment of measuring instrument 800. Further, with regard to the control parameters in C/D 310, for example, there is a parameter related to coating unevenness of resist on a wafer. For example, there are a rotation velocity of a wafer, a drop amount and a drop interval of resist, and the like.

Incidentally, analytical apparatus 600 may be incorporated in measuring instrument 800, exposure apparatus 100, or another processing apparatus. In this case, since analysis related to a line width needs to be performed in measuring instrument 800, exposure apparatus 100, or another processing apparatus in which the analytical apparatus is incorporated, a sending/receiving interface that sends/receives data to/from other apparatuses during execution of a series of processes will be required as in analytical apparatus 600.

Further, substrate processing system 101 related to the embodiment is a system that appropriately performs line width control in exposure apparatus 100 by interaction between exposure apparatus 100 and measuring instrument 800 via analytical apparatus 600. Because they are connected inline to each other, the steps of resist coating, pre-measurement, exposure, post-measurement, development and the like can be performed in a short period, and the measurement results can be analyzed, and then the analytical results can promptly be reflected in respective steps. Therefore, efficient line width control can be performed.

Further, setting value data of control parameters is sent from exposure apparatus 100 to analytical apparatus 600 along with various trace data, however, these data do not need to be sent. Analytical apparatus 600 computes the changes in the setting values of control parameters and sends them to exposure apparatus 100, and exposure apparatus 100 changes the setting values of control parameters in accordance with the changes. Further, trace data that is sent from exposure apparatus 100 to analytical apparatus 600 may be of at least one of a focus, synchronous accuracy and an exposure dose. The trace data is not limited to data on a focus, an exposure dose and synchronous accuracy, and any data may be employed as far as the data relates to the processing states concerning a pattern line width. Further, the exposure conditions are not limited to the foregoing conditions, and any conditions may be designated as far as they are exposure conditions, design conditions of a pattern, control conditions of synchronous control and processing results of other processing apparatuses that affect the line width.

Further, in the embodiment, data obtained from exposure apparatus 100 is to be each control trace data of an exposure dose, synchronous accuracy and a focus, however, exposure apparatus 100 may compute a statistical value of each control error beforehand and send the statistical value to analytical apparatus 600. In this case, the trace data do not need to be sent to analytical apparatus 600.

Incidentally, by making a table with respect to each process such as a resist processing, a development processing and an etching processing, and notifying the analytical apparatus of respective processing conditions, the more optimal line width control is achieved. In other words, a table that shows a relation between the processing states of respective apparatuses other than the exposure apparatus and a line width is controlled, and analysis of a line width may be performed using the table.

From the different view point, analytical apparatus 600 can be regarded as a data control section that obtains available information related to the processing details that affect a line width from various processing apparatuses, and performs overall control of the information so that a line width of a pattern coincides with a design value. In other words, substrate processing system 101 can be regarded as a system that has a data control section that shares and controls data of respective apparatuses related to a line width. By performing such overall control of data related to a line width, it becomes possible to perform well-balanced system adjustment covering various apparatuses when manufacturing devices.

In the embodiment, measuring instrument 800 connects inline to exposure apparatus 100 and the like. However, a measuring instrument may be an offline measuring instrument that does not connect inline to exposure apparatus 100 and track 300. Further, a pre-measuring instrument and a post-measuring instrument may be severally arranged, and one of them may be offline, not be inline.

In the embodiment, exposure apparatus 100 is an exposure apparatus based on a step-and-scan method. However, the present invention is not limited to this, and an exposure apparatus may be based on a step-and-repeat method or other methods. As is typified by the exposure apparatus, types of various apparatuses are not limited to the foregoing apparatuses. Further, the usage of the present invention is not limited to semiconductor manufacturing steps, and the present invention can be applied to manufacturing steps of displays including liquid crystal display devices. Further, it is a matter of course that the present invention can be applied to line width control in all the device manufacturing steps, besides steps in which a device pattern is transferred onto a glass plate, manufacturing steps of thin-film magnetic heads, and manufacturing steps of imaging devices (such as CCD), micromachies, organic EL, DNA chips or the like.

Further, in the embodiment above, a control subject is a line width of a line pattern. However, it is a matter of course that the control subject may be a width of a pattern that is not a line pattern, such as a box mark. That is, the control subject only has to be a size of a pattern.

Further, in the embodiment above, analytical apparatus 600 is to be a PC, as an example. In other words, an analytical processing of analytical apparatus 600 is realized by executing an analytical program by the PC. The analytical program may be installable in the PC via media as is described above, or may be downloadable to the PC through internet. Further, it is a matter of course that analytical apparatus 600 may be constituted by hardware.

While the above-described embodiment of the present invention is the presently preferred embodiment thereof, those skilled in the art of lithography systems will readily recognize that numerous additions, modifications, and substitutions may be made to the above-described embodiment without departing from the spirit and scope thereof. It is intended that all such modifications, additions, and substitutions fall within the scope of the present invention, which is best defined by the claims appended below.

What is claimed is:

1. An analytical apparatus that analyzes information related to a series of processes for forming a device pattern on an object that serves for device manufacturing, the apparatus comprising:
an obtaining unit that obtains information related to processing details that are performed during execution of the series of processes by a processing apparatus that executes at least a part of the series of processes, whereby
based on information obtained by the obtaining unit and information related to an actually measured size of a pattern formed on the object, a causal relation between both information is analyzed.

2. The analytical apparatus of claim 1 whereby
based on the actual measurement value of the size of the pattern, abnormality in size of the pattern is detected, and
in the case the abnormality is detected, the causal relation is analyzed.

3. The analytical apparatus of claim 2 whereby
based on a statistical value related to the actual measurement value of the size of the pattern, abnormality in size of the pattern is detected.

4. The analytical apparatus of claim 3 wherein
the statistical value is at least one of a mean value, variation and the sum of the mean value and the variation of the size of the pattern.

5. The analytical apparatus of claim 2 whereby
a pattern whose size is judged to be abnormal is designated as a pattern to be excluded from a subsequent processing subject.

6. The analytical apparatus of claim 5 wherein
the object is a semiconductor substrate, and
a chip that includes a pattern whose size is judged to be abnormal is excluded per chip from a subsequent processing subject.

7. The analytical apparatus of claim 2 wherein
a judgment level of abnormality in size of the pattern is set in plural stages, and
processing details of a processing apparatus to be subsequently executed are designated with respect to each judgment level in accordance with the judgment level.

8. The analytical apparatus of claim 2 wherein
in the case the series of processes is executed in order with respect to each of a plurality of objects, the number of selected objects on which a size of the pattern is measured is increased or decreased in accordance with detection frequency of a pattern whose size is judged to be abnormal, or a position of the object to be measured is changed in accordance with detection distribution.

9. The analytical apparatus of claim 2 whereby
the processing apparatus is notified that abnormality in size of the pattern is detected.

10. The analytical apparatus of claim 1 whereby
in the case the series of processes is executed in order with respect to each of a plurality of objects, the causal relation is analyzed with respect to only selected objects from among the plurality of objects.

11. The analytical apparatus of claim 10 whereby
the number of selected objects on which a size of the pattern is measured is increased or decreased in accordance with detection frequency of a pattern whose size is judged to be abnormal, or a position of the object to be measured is changed in accordance with detection distribution.

12. The analytical apparatus of claim 1 wherein
at least a part of the series of processes is executed by a plurality of processing apparatuses that execute a part of the processes respectively, and
a causal relation of processing details related to a size of the pattern between the plurality of processing apparatuses is analyzed.

13. The analytical apparatus of claim 12 whereby
based on analytical results of the causal relation, at least one processing apparatus that causes a variation factor of a size of the pattern is specified.

14. The analytical apparatus of claim 13 wherein
information related to a size of the pattern is an actual measurement value of the size of the pattern, and
based on a degree of coincidence between an estimated value of a size of the pattern that is estimated from information related to processing details of each of the processing apparatuses and the actual measurement value, at least one processing apparatus that causes a variation factor of a size of the pattern is specified.

15. The analytical apparatus of claim 14 whereby
based on information that was previously obtained and relates to a relation between processing details of each of the processing apparatuses and a size of the pattern, a size of the pattern is estimated.

16. The analytical apparatus of claim 15 wherein
the information related to processing details of each of the processing apparatuses includes information related to processing conditions and a processing state with respect to the object, and
as the information related to a relation between processing details of each of the processing apparatuses and a size of the pattern, information related to a relation between a processing state of each of the processing apparatuses and a size of the pattern is prepared with respect to each of a plurality of different setting values of the processing conditions.

17. The analytical apparatus of claim 16 wherein
the information related to processing details of each of the processing apparatuses further includes processing results with respect to the object, and
as the information related to a relation between processing details of each of the processing apparatuses and a size of the pattern, information related to a relation between a processing state of each of the processing apparatuses and a size of the pattern is prepared with respect to each of a plurality of different setting values of the processing conditions and each of processing results of others of the processing apparatuses.

18. The analytical apparatus of claim 1 wherein
at least a part of the series of processes is executed by at least one processing apparatus that includes at least one of at least one exposure apparatus that transfers a pattern onto the object, at least one pre-processing apparatus that executes a process before the transfer of the pattern and at least one post-processing apparatus that executes a process after the transfer of the pattern.

19. The analytical apparatus of claim 18 wherein
the pre-processing apparatus includes at least one of a coating apparatus that performs coating on the object with a photosensitive agent and a pre-measuring apparatus that measures a state of the object and a pre-inspecting apparatus that inspects a state of the object, and
the post-processing apparatus includes at least one of a developing apparatus that develops a pattern that is transferred and formed on the object, an etching apparatus that performs etching of the object according to the pattern, a post-measuring apparatus that measures a size of the pattern and an inspecting apparatus of the pattern.

20. The analytical apparatus of claim 1 wherein
at least a part of the series of processes is executed by a plurality of processing apparatuses that execute a part of the processes respectively, and
based on the information related to processing details of each of the processing apparatuses, at least one processing detail that causes a variation factor of a size of the pattern in each of the processing apparatuses is specified.

21. The analytical apparatus of claim 20 whereby
based on comparison results between statistical values of processing details of each of the processing apparatuses and stipulated values of the processing details, at least one processing detail that causes a variation factor of a size of the pattern in each of the processing apparatuses is specified.

22. The analytical apparatus of claim 21 wherein
the statistical values of processing details of each of the processing apparatuses are at least one of a movement mean value and movement standard deviation of information related to a processing state while the pattern is formed on the object.

23. The analytical apparatus of claim 20 whereby
adjustment information used to adjust the processing detail that is specified as a variation factor of a size of the pattern is computed.

24. The analytical apparatus of claim 23 whereby
based on information that was previously obtained and relates to a relation between processing details of each of the processing apparatuses and a size of the pattern, the adjustment information is computed.

25. The analytical apparatus of claim 24 whereby
referring to information that was previously obtained and relates to a relation between processing details of each of the processing apparatuses and a size of the pattern, the adjustment information is computed so that influence on a size of the pattern by the processing detail that is specified as the variation factor is canceled out.

26. The analytical apparatus of claim 24 whereby
referring to information that was previously obtained and relates to a relation between processing details of each of the processing apparatuses and a size of the pattern, processing details that are effective for changing a size of the pattern is focused on and the adjustment information thereof is computed.

27. The analytical apparatus of claim 24 whereby
in the case information related to a relation between a processing state of each of the processing apparatuses and a size of the pattern is prepared with respect to each of a plurality of different setting values of the processing conditions of each of the processing apparatuses as the information related to a relation between processing details of each of the processing apparatuses and a size of the pattern, and in the case the change of the processing conditions is more effective for correcting a size of the pattern, adjustment information used to adjust the setting values of the processing conditions is computed.

28. The analytical apparatus of claim 23 whereby
in the case abnormality in size of the pattern is not detected, a processing detail to be adjusted is restricted to a processing detail that can be changed while continuing a processing to the object.

29. The analytical apparatus of claim 23 wherein
the plurality of processing apparatuses include the exposure apparatus,
information related to processing details of the exposure apparatus includes at least one of information related to an image-forming state of an image of a pattern on the object, information related to relative position deviation of the object with respect to the image of the pattern, and information related to energy of an energy beam used to transfer the image of the pattern onto the object, and
the processing conditions include at least one of an exposure condition used to transfer the pattern, a design condition of the pattern, a control condition of a relative position between the pattern and the object, and a condition related to a processing result of another processing apparatus that performs a processing before the transfer of the pattern.

30. The analytical apparatus of claim 29 wherein
the information related to an image-forming state of the image of the pattern on the object is information on a surface shape datum of the object.

31. The analytical apparatus of claim 23 whereby
one of the processing apparatuses that corresponds to the computed adjustment information is notified of the adjustment information.

32. A processing apparatus that executes at least a part of a series of processes to form a pattern on an object, the apparatus comprising:
the analytical apparatus of claim 1.

33. A measuring apparatus that measures a size of a pattern formed on an object, the apparatus comprising:
the analytical apparatus of claim 1.

34. An exposure apparatus that transfers a pattern onto an object, the apparatus comprising:
the analytical apparatus of claim 1.

35. An analytical method in which information related to a series of processes to form a pattern on an object is analyzed, the method comprising:
analyzing processing details of a processing apparatus that executes at least a part of the series of processes, using the analytical apparatus of claim 1.

36. A processing apparatus that executes at least a part of a series of processes for forming a device pattern on a plurality of objects that serve for device manufacturing, whereby
in the middle of sequentially executing at least a part of the series of processes to the plurality of objects, information related to processing details that relates to a size of the pattern is output.

37. The processing apparatus of claim 36 wherein
the processing details include at least one of processing conditions, a processing state and processing results with respect to the object in the processing apparatus.

38. The processing apparatus of claim 36 wherein
the processing apparatus is any one of a coating apparatus that performs coating on the object with a photosensitive agent, a pre-measuring apparatus that measures a state of the object, a developing apparatus that develops a pattern that is transferred and formed on the object, an etching apparatus that performs etching of the object according to the pattern, a post-measuring apparatus that measures a size of the pattern, and an inspecting apparatus of the pattern.

39. A measuring apparatus that measures a size of a pattern formed on an object whereby
information related to measurement conditions of a size of the pattern and information related to the measurement state can be output.

40. The measuring apparatus of claim 39 wherein
the information related to the measurement state includes information related to a measurement error of a size of the pattern.

41. A measuring apparatus that measures a size of a pattern formed on an object that serves for device manufacturing, in the middle of a period in which a series of processes for forming a device pattern on the object is executed, whereby
information related to measurement conditions of a size of the pattern and information related to the measurement state can be output during execution of the series of processes.

42. A measuring apparatus that measures a size of a pattern formed on an object whereby
information related to processing details at the time when the pattern is formed on the object is requested to the outside of the apparatus.

43. A measuring apparatus that measures a size of a pattern formed on a plurality of objects that serve for device manufacturing, in the middle of a period in which a series of processes for forming a device pattern onto the objects is executed, whereby
information related to processing details at the time when the pattern is formed on the objects is requested to the outside of the apparatus during execution of the series of processes.

44. A measuring apparatus that measures a size of a pattern formed on an object, the apparatus having
a receiving section that receives information related to processing details at the time when the pattern is formed on the object from the outside of the apparatus.

45. A measuring apparatus that measures a size of a pattern formed on a plurality of objects that serve for device manufacturing, in the middle of a period in which a series of processes for forming a device pattern on the objects is executed, the apparatus having
a receiving section that receives information related to processing details at the time when the pattern is formed on the objects from the outside of the apparatus during execution of the series of processes.

46. An exposure apparatus that transfers a pattern onto an object whereby
information related to transfer conditions of the pattern onto the object and information related to a transfer state of the pattern onto the object can be output.

47. An exposure apparatus that transfers a device pattern onto a plurality of objects that serve for device manufacturing whereby
information related to transfer conditions of the pattern onto the objects and information related to a transfer state of the pattern onto the objects can be output in the middle of sequentially executing the transfer to the plurality of objects.

48. A substrate processing system that executes a series of processes to form a pattern on an object, the system comprising:
the analytical apparatus of claim 1.

49. A substrate processing system that executes a series of processes to form a pattern on an object, the system comprising:
the processing apparatus of claim 36.

50. A substrate processing system that executes a series of processes to form a pattern on an object, the system comprising:
the measuring apparatus of claim 39.

51. A substrate processing system that executes a series of processes to form a pattern on an object, the system comprising:
the measuring apparatus of claim 41.

52. A substrate processing system that executes a series of processes to form a pattern on an object, the system comprising:
the measuring apparatus of claim 42.

53. A substrate processing system that executes a series of processes to form a pattern on an object, the system comprising:
the measuring apparatus of claim 43.

54. A substrate processing system that executes a series of processes to form a pattern on an object, the system comprising:
the measuring apparatus of claim 44.

55. A substrate processing system that executes a series of processes to form a pattern on an object, the system comprising:
the measuring apparatus of claim 45.

56. A substrate processing system that executes a series of processes to form a pattern on an object, the system comprising:
the exposure apparatus of claim 46.

57. A substrate processing system that executes a series of processes to form a pattern on an object, the system comprising:
the exposure apparatus of claim 47.

58. A substrate processing system that executes a series of processes to form a pattern onto an object, the system comprising:
a data control section that performs overall control of information related to processing details that affect a size of the pattern in each of a plurality of processing apparatuses that execute the series of processes.

59. A program that makes a computer analyze information related to a series of processes for forming a device pattern onto an object that serves for device manufacturing, the program making the computer execute:
a procedure of analyzing a causal relation between information related to processing details that are performed during execution of the series of processes by a processing apparatus that executes at least a part of the series of processes, and information related to an actually measured size of a pattern formed on the object, based on both information.

60. The program of claim 59, further making the computer execute:
a procedure of detecting abnormality in size of the pattern based on the actual measurement value of the size of the pattern, wherein
in the case the abnormality is detected, the program makes the computer execute a procedure of analyzing the causal relation.

61. The program of claim 60, making the computer execute:
a procedure of detecting abnormality in size of the pattern based on a statistical value related to the actual measurement value of the size of the pattern.

62. The program of claim 60, further making the computer execute:
a procedure of designating a pattern whose size is judged to be abnormal as a pattern to be excluded from a subsequent processing subject.

63. The program of claim 62 wherein
the object is a semiconductor substrate, and
as a procedure of designating a pattern to be excluded from a processing subject, the program makes the computer execute a procedure of excluding a chip that includes a pattern whose size is judged to be abnormal per chip from a processing subject of the processes.

64. The program of claim 60, wherein
a judgment level of abnormality in size of the pattern is set in plural stages, and
the program makes the computer execute a procedure of designating processing details of a processing apparatus to be subsequently executed, in accordance with a level of an abnormality degree of a size of the pattern that is judged by the judgment level in plural stages.

65. The program of claim 60, further making the computer execute:
a procedure of increasing or decreasing the number of selected objects on which a size of the pattern is measured in accordance with detection frequency of a pattern whose size is judged to be abnormal, or changing a position of the object to be measured in accordance with detection distribution, in the case the series of processes is executed in order with respect to each of a plurality of objects.

66. The program of claim 60, further making the computer execute:
a procedure of notifying the processing apparatus that abnormality in size of the pattern is detected.

67. The program of claim 59, making the computer execute:
a procedure of analyzing the causal relation with respect to only selected objects from among the plurality of objects, in the case the series of processes is executed in order with respect to each of the plurality of objects.

68. The program of claim 67, further making the computer execute:
a procedure of increasing or decreasing the number of selected objects on which a size of the pattern is measured in accordance with detection frequency of a pattern whose size is judged to be abnormal, or changing a position of the object to be measured in accordance with detection distribution.

69. The program of claim 59 wherein
at least a part of the series of processes is executed by a plurality of processing apparatuses that execute a part of the processes respectively, and
the program makes the computer execute a procedure of analyzing a causal relation of processing details related to a size of the pattern between the plurality of processing apparatuses.

70. The program of claim 69, further making the computer execute:
a procedure of specifying at least one processing apparatus that causes a variation factor of a size of the pattern based on analytical results of the causal relation.

71. The program of claim 70 wherein
information related to a size of the pattern is an actual measurement value of the size of the pattern, and
the program makes the computer execute a procedure of specifying at least one processing apparatus that causes a variation factor of a size of the pattern, based on a degree of coincidence between an estimated value of a size of the pattern that is estimated from information related to processing details of each of the processing apparatuses and the actual measurement value.

72. The program of claim 71, making the computer execute:
a procedure of estimating a size of the pattern based on information that was previously obtained and relates to a relation between processing details of each of the processing apparatuses and a size of the pattern.

73. The program of claim 72 wherein
the information related to processing details of each of the processing apparatuses includes information related to processing conditions and a processing state with respect to the object, and
as the information related to a relation between processing details of each of the processing apparatuses and a size of the pattern, information related to a relation between a processing state of each of the processing apparatuses and a size of the pattern is prepared with respect to each of a plurality of different setting values of the processing conditions.

74. The program of claim 73 wherein
the information related to processing details of each of the processing apparatuses further includes processing results with respect to the object, and
as the information related to a relation between processing details of each of the processing apparatuses and a size of the pattern, information related to a relation between a processing state of each of the processing apparatuses and a size of the pattern is prepared with respect to each of a plurality of different setting values of the processing conditions and each of processing results of others of the processing apparatuses.

75. The program of claim 74, further making the computer execute:
a procedure of specifying at least one processing detail that causes a variation factor of a size of the pattern in each of the processing apparatuses based on the information related to processing details of each of the processing apparatuses.

76. The program of claim 75, making the computer execute:
a procedure of specifying at least one processing detail that causes a variation factor of a size of the pattern in each of the processing apparatuses, based on comparison results between statistical values of processing details of each of the processing apparatuses and stipulated values of the processing details.

77. The program of claim 76, further making the computer execute:
a procedure of computing adjustment information used to adjust the processing detail that is specified as a variation factor of a size of the pattern.

78. The program of claim 77, making the computer execute:
a procedure of computing the adjustment information based on information that was previously obtained and relates to a relation between processing details of each of the processing apparatuses and a size of the pattern.

79. The program of claim 78, making the computer execute:
a procedure of computing the adjustment information so that influence on a size of the pattern by the processing detail that is specified as the variation factor is canceled out, referring to information that was previously obtained and relates to a relation between processing details of each of the processing apparatuses and a size of the pattern.

80. The program of claim 78, making the computer execute:
a procedure of focusing on processing details that are effective for changing a size of the pattern and computing the adjustment information thereof, referring to information that was previously obtained and relates to a relation between processing details of each of the processing apparatuses and a size of the pattern.

81. The program of claim 77, making the computer execute:
a procedure of computing adjustment information used to adjust processing conditions of each of the processing apparatuses, in the case information related to a relation between a processing state of each of the processing apparatuses and a size of the pattern is prepared with respect to each of a plurality of different setting values of the processing conditions as the information related to a relation between processing details of each of the processing apparatuses and a size of the pattern, and in the case the change of the processing conditions is more effective for correcting a size of the pattern.

82. The program of claim 77, further making the computer execute:
a procedure of restricting a processing detail to be adjusted to a processing detail that can be changed while continuing a processing to the object, in the case abnormality in size of the pattern is not detected.

83. The program of claim 77, further making the computer execute:
a procedure of notifying one of the processing apparatuses of the computed adjustment information.
